(19) United States
(12) Patent Application Publication
(10) Pub. No.: US 2012/0280696 A1
(43) Pub. Date: Nov. 8, 2012

(54) TEST CHIP AND CHIP TEST SYSTEM USING THE SAME

(75) Inventor: Ren-Hong Luo, Hsinchu City (TW)

(73) Assignee: NOVATEK MICROELECTRONICS CORP., Hsinchu (TW)

(21) Appl. No.: 13/177,511

(22) Filed: Jul. 6, 2011

(30) Foreign Application Priority Data
May 5, 2011 (TW) 100115767

(51) Int. Cl. G01R 31/02

(52) U.S. Cl. 324/537

(57) ABSTRACT

A chip test system including a chip under test, a test chip, and a test equipment is provided. The chip under test receives a test input data and provides a test output data according to the test input data. The test chip performs at least one of a skew test, a jitter test, and a setup/hold time test on the chip under test by using the test input data and determines whether a test result falls within a predetennined range. The test equipment provides the test input data and inputs the test input data into the chip under test through the test chip.

### CROSS-REFERENCE TO RELATED APPLICATION

This application claims the priority benefit of Taiwan application serial no. 100115767, filed on May 5, 2011. The entirety of the above-mentioned patent application is hereby incorporated by reference herein and made a part of this specification.

### BACKGROUND OF THE INVENTION

1. Field of the Invention

The invention generally relates to a test device and a test system using the same, and more particularly, to a test chip and a chip test system using the same.

2. Description of Related Art

In recent years, the display panel technology has matured. In addition, both the size and resolution of display panels have been increased in order to meet the increasing consumer demand. However, when the resolution and size of a display panel are increased, the operating frequency inside the display panel also increases. Presently, the transmission interfaces of timing controller and source driver inside a display panel are usually dedicated clock interfaces.

The transmission speed and transmission quality of transmission interfaces have increased along with the size and resolution of display panels. Due to the relationship between the high-speed serial data and the clock of a dedicated clock interface, such factors as channel to channel skew, clock jitter, and set-up and hold time are very critical in mass chip production. However, if these factors are tested by using a high-speed mass production equipment, the test process will be very time-consuming and costly. Thereby, a low-cost and time-saving test system is desired.

### SUMMARY OF THE INVENTION

Accordingly, the invention is directed to a chip test system for testing a chip under test, wherein the cost of mass chip production is greatly reduced and the test accuracy is improved.

The invention is directed to a test chip for testing a chip under test, wherein the cost of mass chip production is greatly reduced and the test accuracy is improved.

The invention provides a chip test system including a chip under test, a test chip, and a test equipment. The chip under test receives a test input data and provides a test output data according to the test input data. The test chip performs at least one of a skew test, a jitter test, and a setup/hold time test on the chip under test by using the test input data and determines whether a test result falls within a predetermined range. The test equipment provides the test input data and inputs the test input data into the chip under test through the test chip.

The invention provides a test chip suitable for testing a chip under test in a chip test system. The test chip includes a test unit and a determination unit. The test unit performs at least one of a skew test, a jitter test, and a setup/hold time test on the chip under test. The determination unit determines whether a test result falls within a predetermined range.

According to an embodiment of the invention, the chip under test receives a test input data and provides a test output data according to the test input data. The test output data includes a first signal and a second signal. The test chip includes a skew test unit. The skew test unit includes a first skew test channel and a second skew test channel. The first skew test channel is suitable for performing the skew test on the second signal and the first signal leading the second signal. The second skew test channel is suitable for performing the skew test on the first signal and the second signal leading the first signal.

According to an embodiment of the invention, the first skew test channel and the second skew test channel respectively include a skew sampling unit, a delay line unit, a register unit, and a control unit. The skew sampling unit performs a skew sampling operation on the first signal and the second signal to obtain a signal skew between the first signal and the second signal. The delay line unit quantizes the sampled first signal and the sampled second signal. The register unit stores a quantization result of the delay line unit. The control unit provides an operation sequence to the skew sampling unit, the delay line unit, and the register unit.

According to an embodiment of the invention, the test output data includes a third signal. The test chip includes a jitter test unit. The jitter test unit includes a one-period sampling unit, a delay line unit, a register unit, and a control unit. The one-period sampling unit performs a one-period sampling operation on the third signal to obtain at least one jitter pattern of the third signal, wherein the jitter pattern includes a period jitter and a cycle-to-cycle jitter. The delay line unit quantizes the sampled third signal. The register unit stores a quantization result of the delay line unit. The control unit provides an operation sequence to the one-period sampling unit, the delay line unit, and the register unit.

According to an embodiment of the invention, the test output data includes a fourth signal and a fifth signal. The test chip includes a setup/hold time test unit. The setup/hold time test unit includes an edge sampling unit, a delay line unit, a register unit, and a control unit. The edge sampling unit performs an edge sampling operation on the fourth signal and the fifth signal, wherein the edge sampling operation includes sampling rising edges and falling edges of the fourth signal and the fifth signal to obtain a setup time and a hold time between the fourth signal and the fifth signal. The delay line unit quantizes the sampled fourth signal and the sampled fifth signal. The register unit stores a quantization result of the delay line unit. The control unit provides an operation sequence to the edge sampling unit, the delay line unit, and the register unit.

As described above, in an exemplary embodiment of the invention, a chip test system tests such signal factors as skew, jitter, and set-up and hold time of a chip under test through a test chip so that the cost of mass chip production can be greatly reduced and the test accuracy can be improved.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an implementation diagram of a chip test system according to an embodiment of the invention.

FIG. 2 is a diagram illustrating functional blocks inside a test chip in FIG. 1.

FIG. 3 is an implementation diagram of a vernier delay line according to an embodiment of the invention.

FIG. 4 is a diagram illustrating functional blocks inside a skew test unit in FIG. 2.

FIG. 5 is a timing diagram of signals in the skew test unit in FIG. 4.

FIG. 6 is a diagram illustrating functional blocks inside a jitter test unit in FIG. 2.

FIG. 7 is a timing diagram of signals in the jitter test unit in FIG. 6.

FIG. 8 is a diagram illustrating functional blocks inside the jitter test unit in FIG. 2.

FIG. 9A is a timing diagram of a fourth signal and a fifth signal in FIG. 8.

FIG. 9B illustrates patterns of the fourth signal and the fifth signal in FIG. 8 and inverted signals thereof.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

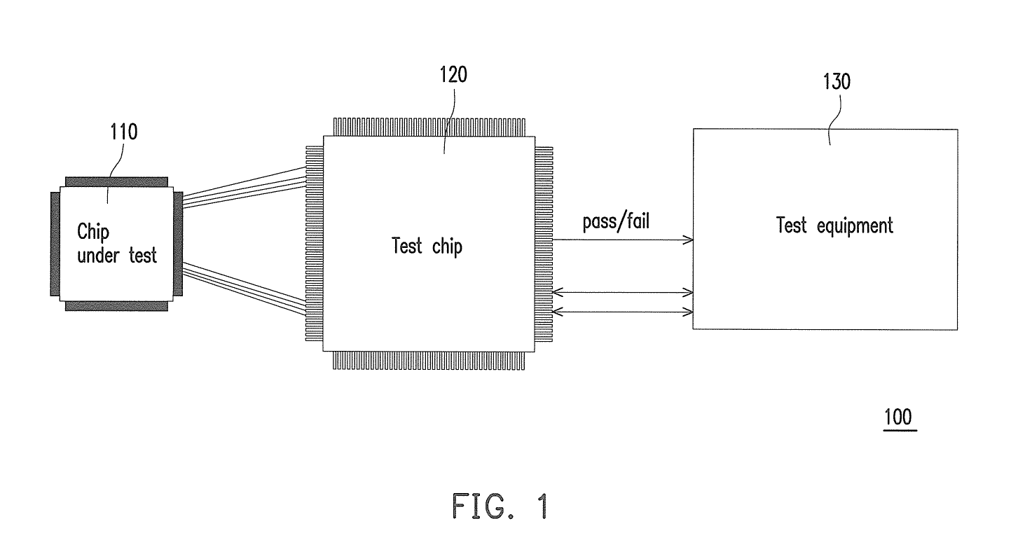

FIG. 1 is an implementation diagram of a chip test system according to an embodiment of the invention. Referring to FIG. 1, the chip test system 100 in the present embodiment includes a chip under test 110, a test chip 120, and a test equipment 130. The test equipment 130 performs various electrical tests on the chip under test 110 by using test input data, such as test vectors or test patterns. Herein the chip test system 100 can perform at least a skew test, a jitter test, and a setup/hold time test on the chip under test 110 through the test chip 120, so as to reduce the mass production cost and improve the test accuracy.

In the present embodiment, the test equipment 130 provides a test input data to the chip under test 110, so as to allow the chip under test 110 to issue a signal to be tested to the test chip 120. Meanwhile, the test equipment 130 sets the test chip 120. After the chip under test 110 receives the test input data, it provides a test output data to the test chip 120 according to the test input data. The test chip 120 performs at least a skew test, a jitter test, and a setup/hold time test on the chip under test 110 and determines whether the test result falls within a predetermined range. The test chip 120 provides a pass signal or a fail signal to the test equipment 130 according to the determination result, so as to allow the test equipment 130 to categorize and screen the quality of the chip under test 110. For example, if the test result falls within a predetermined range, the test chip 120 outputs a pass signal to the test equipment 130. Contrarily, if the test result does not fall within the predetermined range, the test chip 120 outputs a fail signal to the test equipment 130.

Thereby, in an exemplary embodiment of the invention, the test chip 120 is a chip circuit which is different from the test equipment 130 and comes without any build-in self test (BIST) (or referred to as a chip circuit with build-out self test (BOST)). The test chip 120 performs a skew test, a jitter test, and/or a set-up and hold time test on test output data in the low-voltage differential signalling (LVDS) format. However, the invention is not limited thereto.

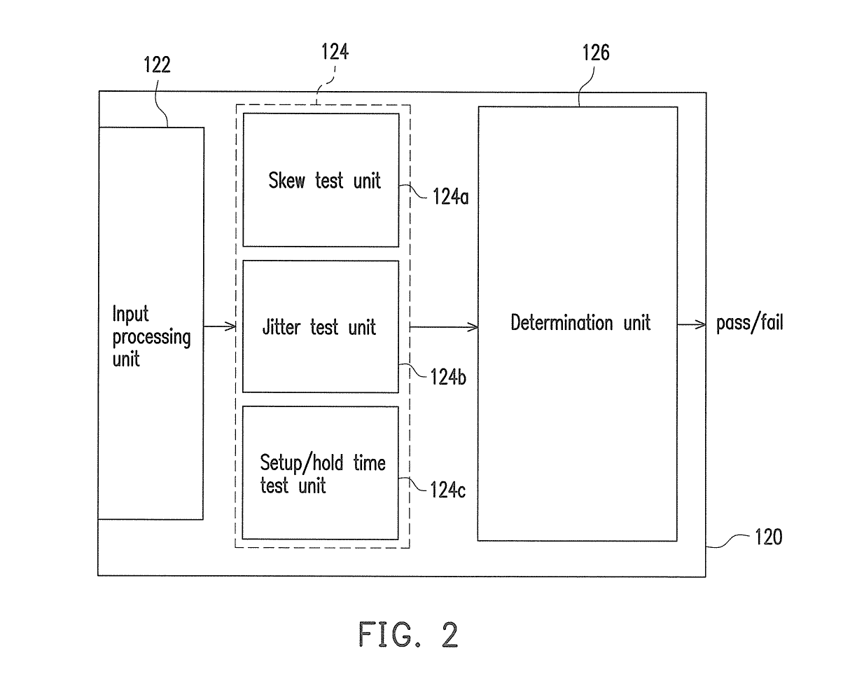

FIG. 2 is a diagram illustrating functional blocks inside the test chip in FIG. 1. Referring to FIG. 2, the test chip 120 in the present embodiment includes an input processing unit 122, a test unit 124, and a determination unit 126. The test unit 124 includes a skew test unit 124a, a jitter test unit 124b, and a setup/hold time test unit 124c. The input processing unit 122 performs different analog signal processing (for example, buffering and amplifying) on the test output data provided by the chip under test 110. The test unit 124 receives the processed test output data and performs at least one of the skew test, the jitter test, and the setup/hold time test on the chip under test 110. Moreover, the determination unit 126 determines whether the test result falls within a predetermined range. Additionally, unlike the input processing unit 122, the determination unit 126 may be a digital signal processing unit and configured to perform digital signal processing on the quantization result provided by the test unit 124.

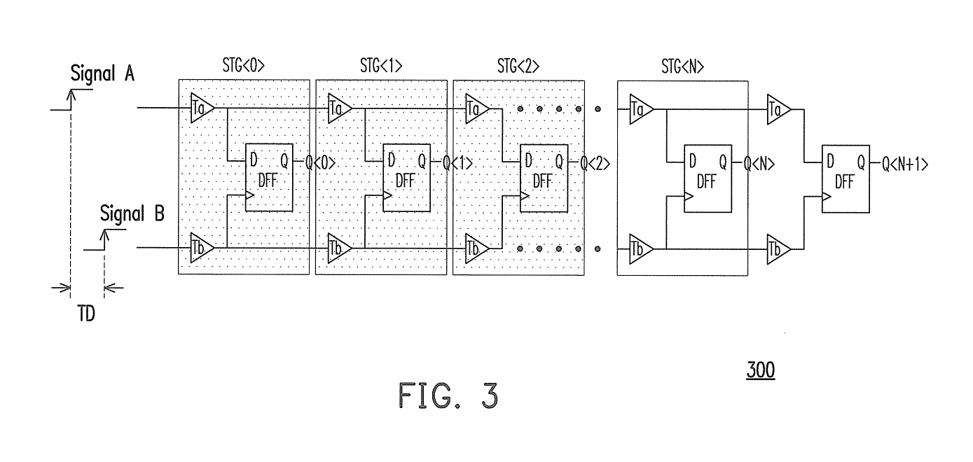

To be specific, in the present embodiment, the test chip 120 may be implemented by adopting a vernier delay line concept, as shown in FIG. 3. However, the invention is not limited thereto. FIG. 3 is an implementation diagram of a vernier delay line according to an embodiment of the invention. Referring to FIG. 3, the vernier delay line 300 in the present embodiment is suitable for quantizing two signals A and B, wherein there is a time difference between the two signals A and B. The vernier delay line 300 includes a plurality of quantization units STG<0>, STG<1>, STG<2>, . . . , and STG<N>which are connected with each other in series. Each quantization unit includes corresponding delay units Ta and Tb and a D flip-flop.

In the present embodiment, the two signals A and B with time difference TD enter a series of delay units Ta and Tb which have a time difference |ta−tb−=Δt. Along with the transmission of the signals A and B in the vernier delay line 300, the time difference between the two signals is gradually reduced from TD to TD−Δt, TD−2Δt, . . . , and TD−NΔ, etc. Thus, the signal A turns from leading the signal B to lagging behind the signal B. Assuming that the signal A lags behind the signal B after they pass through the quantization unit STG<I> (not shown), the D flip-flops of the quantization units STG<0>, STG<1>, . . . , and STG<I> sample quantization data Q<0>, Q<1>, . . . , and Q<I> (not shown, may be 1) and output the quantization data through the corresponding terminals Q thereof when the signal A still leads the signal B. After that, when the signal A lags behind the signal B, the D flip-flops of the quantization units STG<I+1> (not shown), STG<I+2> (not shown), . . . , and STG<N> sample quantization data Q<I+1> (not shown), Q<I+2> (not shown), . . . , and Q<N> (may be 0) and output the quantization data through the corresponding terminals Q thereof.

Thereby, the test unit 124 in the present embodiment quantizes edge timing information of two signals by using the vernier delay line 300, so as to perform subsequent skew test, jitter test, or setup/hold time test on these signals. In the present embodiment, the test unit 124 includes a skew test unit 124a, a jitter test unit 124b, and a setup/hold time test unit 124c for respectively performing a skew test, a jitter test, and a setup/hold time test on the chip under test 110.

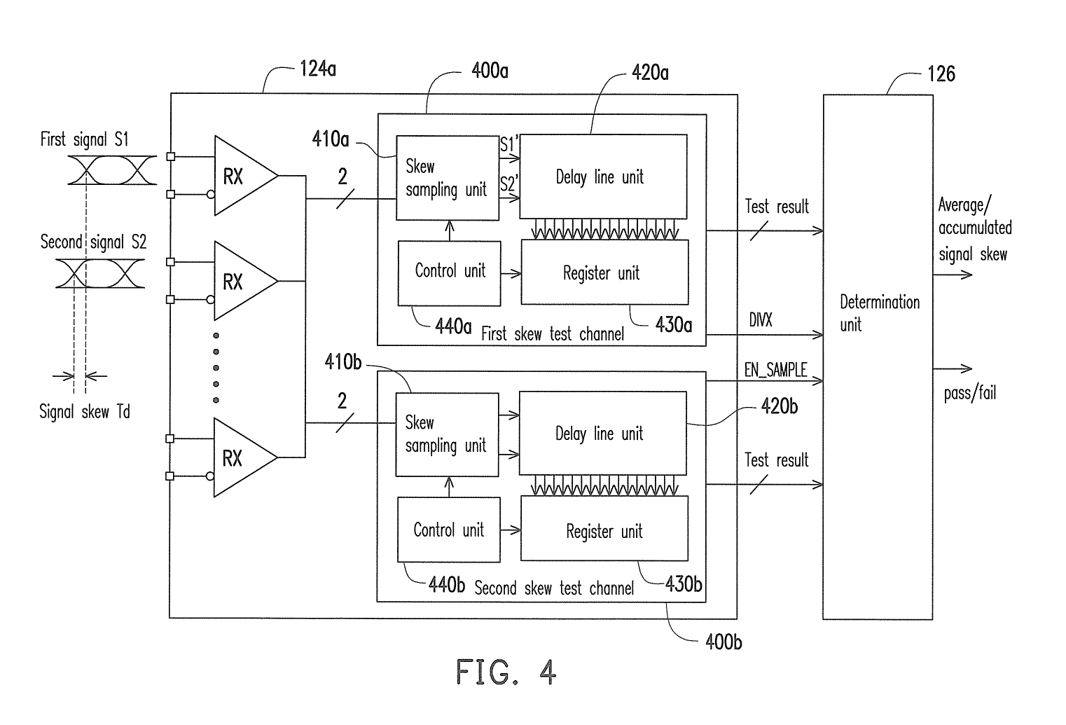

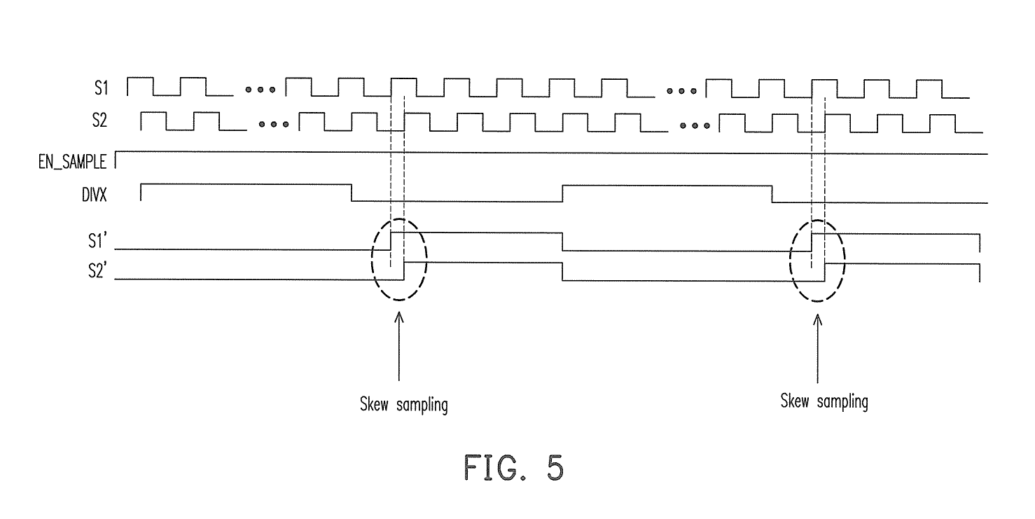

FIG. 4 is a diagram illustrating functional blocks inside the skew test unit in FIG. 2. FIG. 5 is a timing diagram of signals in the skew test unit in FIG. 4. Referring to FIG. 4 and FIG. 5, the skew test unit 124a in the present embodiment includes a first skew test channel 400a and a second skew test channel 400b. In the present embodiment, the test output data of the chip under test 110 contains a first signal S1 and a second signal S2. In order to meet the actual test requirement, the skew test unit 124a in the present embodiment is disposed with two test channels for testing different signal timing patterns. Namely, the first skew test channel 400a is suitable for testing a timing pattern in which the first signal S1 leads the second signal S2, so as to perform the skew test on the second signal S2 and the first signal S1 leading the second signal S2. The second skew test channel 400b is suitable for testing a timing pattern in which the second signal S2 leads the first signal S1, so as to perform the skew test on the first signal S1 and the second signal S2 leading the first signal S1.

The first skew test channel 400a includes a skew sampling unit 410a, a delay line unit 420a, a register unit 430a, and a control unit 440a. The control unit 440a provides an operation sequence to the skew sampling unit 410a, the delay line unit 420a, and the register unit 430a. Generally speaking, the test output data received by the skew test unit 124a through an input amplifier RX thereof is a first signal S1 and a second signal S2 in the LVDS format. When a sample enabling signal EN_SAMPLE is at a high level, the skew sampling unit 410a performs an skew sampling operation on the first signal S1 and the second signal S2 according to an operation sequence provided by the control unit 440a (as shown in FIG. 5) to obtain a first signal S1′ and a second signal S2′, so as to obtain a signal skew Td between the first signal S1′ and the second signal S2′.

Then, the delay line unit 420a quantizes the first signal S1′ and the second signal S2′ by using the vernier delay line in FIG. 3 and stores the quantization result into the register unit 430a. Next, the register unit 430a outputs a plurality of accumulated quantization results to the determination unit 126 as a test result to allow a digital signal processing to be carried out. After that, the determination unit 126 determines whether the test result falls within a predetermined range. If the test result falls within the predetermined range, the determination unit 126 outputs a pass signal to the test equipment 130. Contrarily, if the test result does not fall within the predetermined range, the determination unit 126 outputs a fail signal to the test equipment 130. In addition, in order to increase the test accuracy, the determination unit 126 can perform accumulation and averaging operations on multiple test results according to the design requirement and output the average or accumulated signal skew as tester reference. Moreover, a timing signal DIVX is served as a strobe timing for outputting the test result. In the present embodiment, the timing signal DIVX may be obtained by dividing the frequency of the system clock by 128.

In the present embodiment, the timing pattern in which the first signal S1 leads the second signal S2 is illustrated in FIG. 4, and the first skew test channel 400a is suitable for testing signal skew in such a timing pattern. Unlike the first skew test channel 400a, the second skew test channel 400b is suitable for testing signal skew in such timing pattern that the second signal S2 leads the first signal S1. Similarly, in the present embodiment, the second skew test channel 400b includes a skew sampling unit 410b, a delay line unit 420b, a register unit 430b, and a control unit 440b. The operation of the second skew test channel 400b for testing signal skew of the first signal S1 and the second signal S2 should be understood by those having ordinary knowledge in the art according to the description related to the first skew test channel 400a therefore will not be described herein.

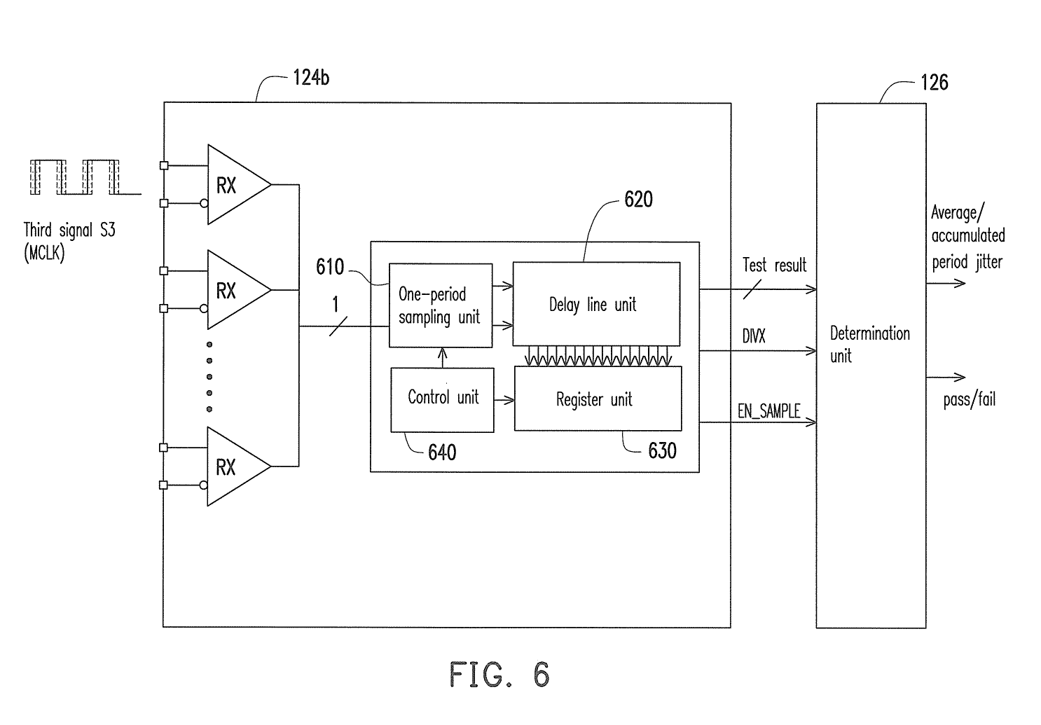

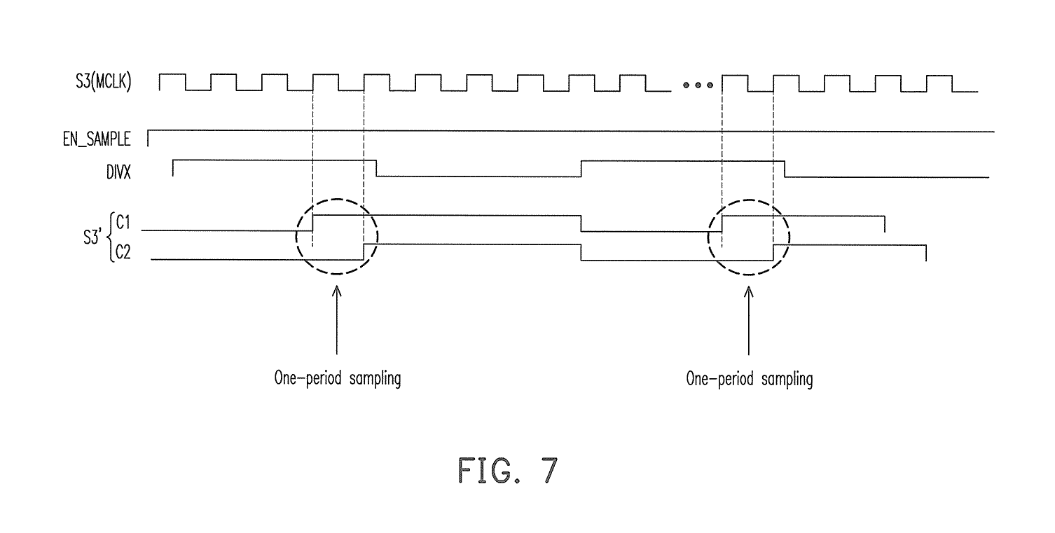

FIG. 6 is a diagram illustrating functional blocks inside the jitter test unit in FIG. 2. FIG. 7 is a timing diagram of signals in the jitter test unit in FIG. 6. Referring to FIG. 6 and FIG. 7, the jitter test unit 124b in the present embodiment includes a one-period sampling unit 610, a delay line unit 620, a register unit 630, and a control unit 640. The control unit 640 provides an operation sequence to the one-period sampling unit, the delay line unit 620, and the register unit 630.

In the present embodiment, the test output data of the chip under test 110 contains a third signal S3. The third signal S3 may be a system clock MCLK. The one-period sampling unit 610 performs an one-period sampling operation on the third signal S3 to obtain a third signal S3′, wherein the third signal S3′ contains period edge signals C1 and C2. Accordingly, the one-period sampling unit 610 obtains a jitter pattern of the third signal S3. Generally speaking, the jitter pattern of a signal may be a period jitter or a cycle-to-cycle jitter. In the present embodiment, the one-period sampling unit 610 can calculate the period jitter and the cycle-to-cycle jitter of the third signal S3 based on different jitter pattern definition according to the design requirement after the sampled third signal S3′ is obtained.

Next, the delay line unit 620 quantizes the third signal S3′ and stores the quantization result into the register unit 630. Thereafter, the register unit 630 outputs a plurality of accumulated quantization results to the determination unit 126 as a test result to allow a digital signal process to be carried out. The determination unit 126 determines whether the test result falls within a predetermined range. If the test result falls within the predetermined range, the determination unit 126 outputs a pass signal to the test equipment 130. Contrarily, if the test result does not fall within the predetermined range, the determination unit 126 outputs a fail signal to the test equipment 130. Similarly, in order to increase test accuracy, the determination unit 126 can perform accumulation and averaging operations on multiple test results according to the design requirement and output the average or accumulated period jitter as tester reference.

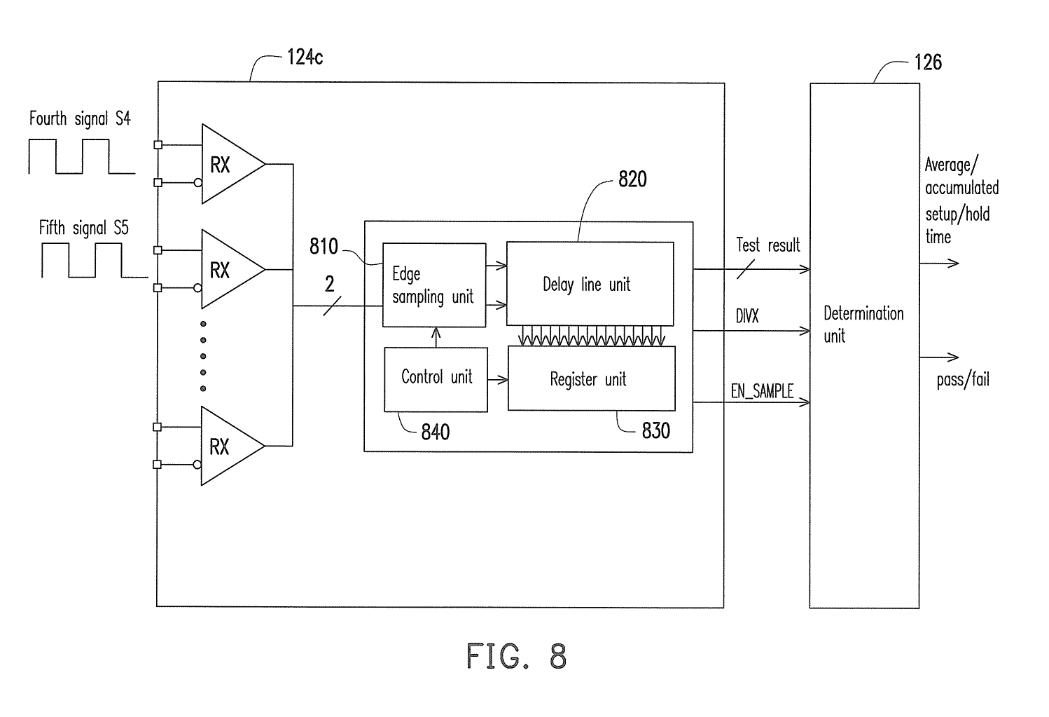

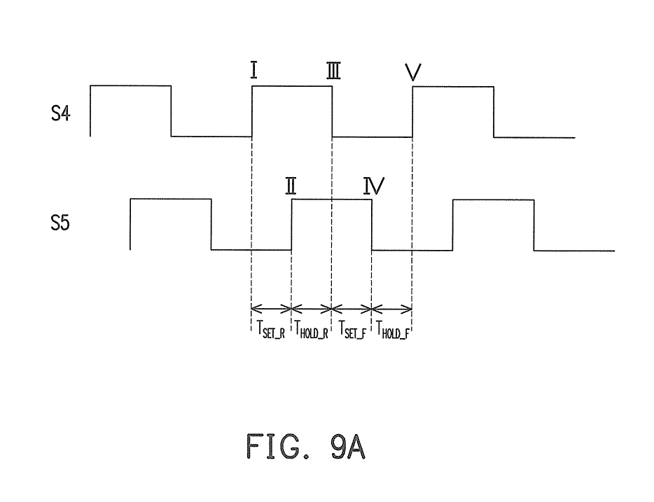

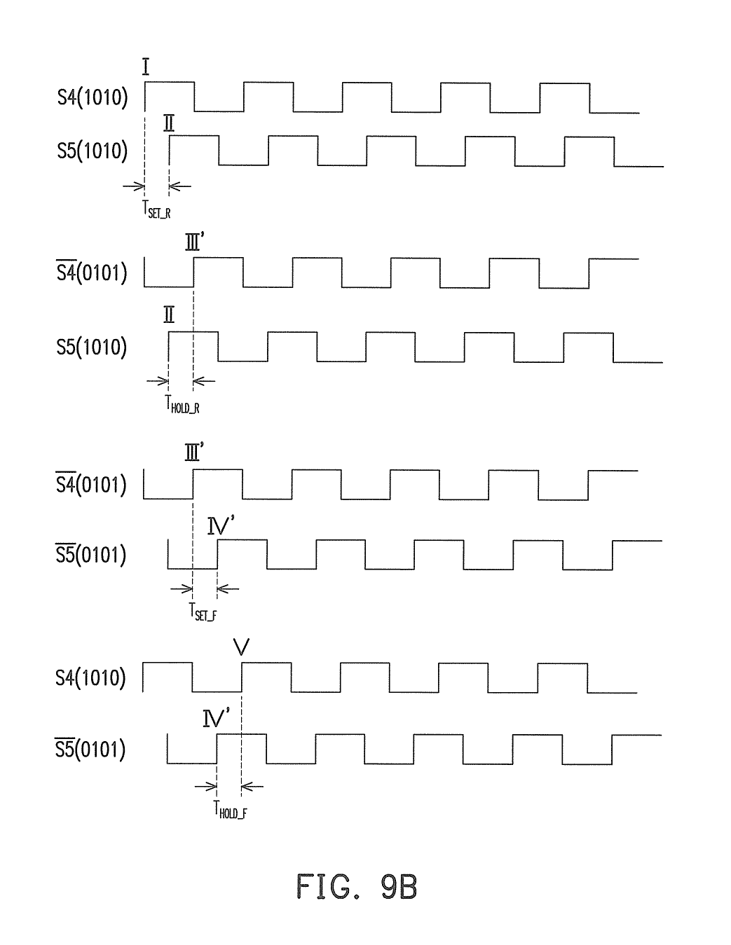

FIG. 8 is a diagram illustrating functional blocks inside the jitter test unit in FIG. 2. FIG. 9A is a timing diagram of a fourth signal and a fifth signal in FIG. 8. FIG. 9B illustrates patterns of the fourth signal and the fifth signal in FIG. 8 and inverted signals thereof. Referring to FIG. 8, FIG. 9A, and FIG. 9B, the jitter test unit 124c in the present embodiment includes an edge sampling unit 810, a delay line unit 820, a register unit 830, and a control unit 840. The control unit 840 provides an operation sequence to the edge sampling unit 810, the delay line unit 820, and the register unit 830.

In the present embodiment, the test output data of the chip under test 110 contains a fourth signal S4 and a fifth signal S5. The fourth signal S4 and the fifth signal S5 may be respectively a data signal DATA and a system clock MCLK. The edge sampling unit 810 performs an edge sampling operation on the fourth signal S4 and the fifth signal S5 to obtain a rising edge IV and a falling edge III of the fourth signal S4 and a rising edge II and a falling edge IV of the fifth signal S5. Accordingly, the edge sampling unit 810 can obtain setup time T_{SET}_{_{—}}_{R} and TSET_{_{—}}_{F} and hold time T_{HLD}_{_{—}}_{R} and T_{HLD}_{_{—}}_{F} between the fourth signal S4 and the fifth signal S5, as shown in FIG. 9A.

To be specific, in the present embodiment, it is assumed that both the fourth signal S4 and the fifth signal S5 have a signal pattern 1010, as shown in FIG. 9B. The edge sampling unit 810 performs an edge sampling operation on the fourth signal S4 and the fifth signal S5 having the signal pattern 1010 to obtain a rising edge I of the fourth signal S4 and a rising edge II of the fifth signal S5, so as to obtain a setup time T_{SET}_{_{—}}_{R} between the two signals. However, if the edge sampling unit 810 is about to obtain the hold time T_{HLD}_{_{—}}_{R} between the fourth signal S4 and the fifth signal S5, the edge sampling unit 810 first inverts the fourth signal S4 to obtain an inverted fourth signal S̅4̅ having a signal pattern of 0101. Then, the edge sampling unit 810 performs the edge sampling operation on the inverted fourth signal S̅4̅ and the fifth signal S5 to obtain a rising edge III′ of the inverted fourth signal S̅4̅ and a rising edge II of the fifth signal S5, so as to obtain the hold time T_{HLD}_{_{—}}_{R} between the fourth signal

S4 and the fifth signal S5.

Similarly, if the edge sampling unit 810 is about to obtain the setup time T_{SET}_{_{—}}_{F} between the fourth signal S4 and the fifth signal S5, the edge sampling unit 810 first inverts the fourth signal S4 and the fifth signal S5 to obtain an inverted fourth signal S̅4̅ and an inverted fifth signal S̅5̅ both having the signal pattern of 0101. Then, the edge sampling unit 810 performs an edge sampling operation on the inverted fourth signal S̅4̅ and the inverted fifth signal S̅5̅ to obtain a rising edge III′ of the inverted fourth signal S̅4̅ and a rising edge IV′ of the inverted fifth signal S̅5̅, so as to obtain the setup time T_{SET}_{_{—}}_{F} between the fourth signal S4 and the fifth signal S5. If the edge sampling unit 810 is about to obtain the hold time T_{HLD}_{_{—}}_{F} between the fourth signal S4 and the fifth signal S5, the edge sampling unit 810 first inverts the fifth signal S5 to obtain an inverted fifth signal S̅5̅ having a signal pattern of 0101. Then, the edge sampling unit 810 performs an edge sampling operation on the fourth signal S4 and the inverted fifth signal S̅5̅ to obtain a rising edge V of the fourth signal S4 and a rising edge IV′ of the inverted fifth signal S̅5̅, so as to obtain the hold time T_{HLD}_{_{—}}_{F} between the fourth signal S4 and the fifth signal S5.

Thereafter, the delay line unit 820 quantizes the sampled fourth signal S4 and fifth signal S5 and stores the quantization result into the register unit 830. Next, the register unit 830 outputs a plurality of accumulated quantization results to the determination unit 126 as a test result, so as to allow a digital signal processing to be carried out. The determination unit 126 deteimines whether the test result falls within a predetermined range. If the test result falls within the predeteimined range, the determination unit 126 outputs a pass signal to the test equipment 130. Contrarily, if the test result does not fall within the predetermined range, the determination unit 126 outputs a fail signal to the test equipment 130. Similarly, in order to increase the test accuracy, the determination unit 126 can perform accumulation and averaging operations on multiple test results according to the design requirement and output the average or accumulated setup time T_{SET}_{_{—}}_{R} and T_{SET}_{_{—}}_{F} and hold time T_{HLD}_{_{—}}_{R} and T_{HLD}_{_{—}}_{F} as tester reference.

In summary, in an exemplary embodiment of the invention, a chip test system tests such signal factors as skew, jitter, and set-up and hold time of a chip under test through a test chip so that the cost of mass chip production can be greatly reduced and the test accuracy can be improved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A chip test system, comprising:
a chip under test receiving a test input data and providing a test output data according to the test input data;
a test chip performing at least one of a skew test, a jitter test, and a setup/hold time test on the chip under test by using the test input data and determining whether a test result falls within a predetermined range; and
a test equipment, providing the test input data and inputting the test input data into the chip under test through the test chip.

2. The chip test system according to claim 1, wherein the test chip comprises:
a test unit performing at least one of the skew test, the jitter test, and the setup/hold time test on the chip under test; and
a determination unit determining whether the test result falls within the predetermined range.

3. The chip test system according to claim 2, wherein the test output data comprises a first signal and a second signal, the test chip comprises a skew test unit, and the skew test unit comprises:
a first skew test channel performing the skew test on the second signal and the first signal leading the second signal; and
a second skew test channel performing the skew test on the first signal and the second signal leading the first signal.

4. The chip test system according to claim 3, wherein the first skew test channel and the second skew test channel respectively comprise:
a skew sampling unit performing a skew sampling operation on the first signal and the second signal to obtain a signal skew between the first signal and the second signal;
a delay line unit quantizing the sampled first signal and the sampled second signal;
a register unit storing a quantization result of the delay line unit; and
a control unit providing an operation sequence to the skew sampling unit, the delay line unit, and the register unit.

5. The chip test system according to claim 2, wherein the test output data comprises a third signal, the test chip comprises a jitter test unit, and the jitter test unit comprises:
a one-period sampling unit performing a one-period sampling operation on the third signal to obtain at least one jitter pattern of the third signal, wherein the jitter pattern comprises a period jitter and a cycle-to-cycle jitter;
a delay line unit quantizing the sampled third signal;
a register unit storing a quantization result of the delay line unit; and
a control unit providing an operation sequence to the one-period sampling unit, the delay line unit, and the register unit.

6. The chip test system according to claim 2, wherein the test output data comprises a fourth signal and a fifth signal, the test chip comprises a setup/hold time test unit, and the setup/hold time test unit comprises:
an edge sampling unit performing an edge sampling operation on the fourth signal and the fifth signal, wherein the edge sampling operation comprises sampling rising edges and falling edges of the fourth signal and the fifth signal to obtain a setup time and a hold time between the fourth signal and the fifth signal;
a delay line unit quantizing the sampled fourth signal and the sampled fifth signal;
a register unit storing a quantization result of the delay line unit; and
a control unit providing an operation sequence to the edge sampling unit, the delay line unit, and the register unit.

7. A test chip, suitable for testing a chip under test in a chip test system, the test chip comprising:
a test unit performing at least one of a skew test, a jitter test, and a setup/hold time test on the chip under test; and
a determination unit determining whether the test result falls within the predetermined range.

8. The test chip according to claim 7, wherein the chip under test receives a test input data and provides a test output data according to the test input data, the test output data comprises a first signal and a second signal, the test chip comprises a skew test unit, and the skew test unit comprises:
a first skew test channel performing the skew test on the second signal and the first signal leading the second signal; and
a second skew test channel performing the skew test on the first signal and the second signal leading the first signal.

9. The test chip according to claim 8, wherein the first skew test channel and the second skew test channel respectively comprise:
a skew sampling unit performing a skew sampling operation on the first signal and the second signal to obtain a signal skew between the first signal and the second signal;
a delay line unit quantizing the sampled first signal and the sampled second signal;
a register unit storing a quantization result of the delay line unit; and
a control unit providing an operation sequence to the skew sampling unit, the delay line unit, and the register unit.

10. The test chip according to claim 8, wherein the test output data comprises a third signal, the test chip comprises a jitter test unit, and the jitter test unit comprises:
a one-period sampling unit performing a one-period sampling operation on the third signal to obtain at least one jitter pattern of the third signal, wherein the jitter pattern comprises a period jitter and a cycle-to-cycle jitter;
a delay line unit quantizing the sampled third signal;
a register unit storing a quantization result of the delay line unit; and
a control unit providing an operation sequence to the one-period sampling unit, the delay line unit, and the register unit.

11. The test chip according to claim 8, wherein the test output data comprises a fourth signal and a fifth signal, the test chip comprises a setup/hold time test unit, and the setup/hold time test unit comprises:
an edge sampling unit performing an edge sampling operation on the fourth signal and the fifth signal, wherein the edge sampling operation comprises sampling rising edges and falling edges of the fourth signal and the fifth signal to obtain a setup time and a hold time between the fourth signal and the fifth signal;
a delay line unit quantizing the sampled fourth signal and the sampled fifth signal;
a register unit storing a quantization result of the delay line unit; and
a control unit providing an operation sequence to the edge sampling unit, the delay line unit, and the register unit.
